(19) United States
(12) Patent Application Publication
(10) Pub. No.: US 2008/0297292 A1
(43) Pub. Date: Dec. 4, 2008

(54) Radio Frequency Device with Magnetic Element, Method for Making Such a Magnetic Element

(76) Inventors: Bernard Viala, Sassenage (FR); Sandrine Couderc, Grenoble (FR); Pascal Ancey, Revel (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(21) Appl. No.: 11/996,332

(22) PCT Filed: Jul. 19, 2006
(86) PCT No.: PCT/FR2006/001765

§ 371 Date: Jul. 15, 2008

(30) Foreign Application Priority Data
Jul. 21, 2005 (FR) 0507768

(51) Int. Cl. H01F 10/12; C23C 14/46; C23C 14/35

(52) U.S. Cl. 335/296; 204/192.15; 204/192.11

(57) ABSTRACT

A radiofrequency device may include an electrically conducting element associated with at least one continuous magnetic element. The first continuous magnetic element may include a substrate coated with a magnetic film having a granular structure, with grains that are inclined to the normal to the substrate, or a columnar texture inclined to the normal of the substrate.

### FIELD OF THE INVENTION

The invention relates to radiofrequency devices comprising a conducting element associated with a magnetic element, in particular, radiofrequency inductive elements, but also, for example, radiofrequency filters or resonators.

### BACKGROUND OF THE INVENTION

Currently, for radiofrequency applications, such devices generally only use discontinuous magnetic circuits. In other words, the radiofrequency applications include a plurality of elementary parts with finite dimensions because of a limitation that is intrinsic to soft magnetic materials.

Indeed, these materials generally must be of an anisotropic nature characterized by a field called an anisotropy field (Hk) whose principal origin is associated with a preferential chemical ordering at the scale of the crystal lattice. This effect is generally obtained by conventional deposition of the material, by a plasma or electrochemical means, in the presence of an applied magnetic field. It is an intrinsic contribution that preferentially depends on the chemical composition of the magnetic alloy. The amplitude of this effect generally remains modest with Hk typically less than or equal to 20 Oe. Under these conditions, the ferromagnetic resonance frequency, which forms the upper limit for the dynamic application of these materials, remains too low (˜2 GHz) with regard to the targeted applications, notably telephones.

In the case of inductors, in order to meet the requirements of an inductive operation with low dissipation, this frequency must be pushed up by a factor of around 3 depending on the application frequencies which are currently typically from around 0.9 to around 2.4 GHz. In the case of filters, in order to meet the requirements of an inductive operation with high dissipation, the idea is to use the ferromagnetic resonance absorption phenomenon. The latter must coincide, for example, with one or more of the harmonics (or image frequencies) of the base-frequency signal, whose current application frequencies are typically from around 0.9 to around 2.4 GHz. It is therefore essential to reach ferromagnetic resonance frequency values of around 6 GHz and more.

This is made possible by means of an extrinsic effect known as “shape effect” which includes artificially reinforcing the intrinsic magnetic anisotropy of the material (Hk) by the contribution of the demagnetizing field (Hd), which depends on the geometry and on the dimensions involved.

More precisely, the smaller the width of the magnetic element in the direction perpendicular to that of the easy axis of magnetization (hard axis of magnetization) is reduced, the greater the contribution of the demagnetizing field. For example, in order to meet the requirement for a ferromagnetic resonance frequency higher than 6 GHz using a material with a saturation magnetization of around 1 T, a demagnetizing field (Rd) higher than 400 Oe will need to be added to the natural anisotropy field (Hk), which is around 200 Oe. This implies a maximum dimension of the magnetic element in the hard axis of around 25 μm, which is of the same order of magnitude as the pitch (spiral turn+inter-turn width) of the radiofrequency (RF) inductors, for example. It will then be readily understood that, in order to cover the surface of a spiral inductor or to fill the core of a solenoidal inductor, a plurality of separate magnetic elements will be required. These are therefore discontinuous magnetic circuits whose main difficulty is related to the optimization of the ratio between the width of the magnetic element and the separation distance between magnetic elements. This is made all the more difficult if it is desired to close the magnetic flux in order to obtain a better electromagnetic confinement around the inductive element (sandwiched spiral or toroidal solenoid).

Consequently, by virtue of the requirement for a discontinuous nature of the magnetic element itself and by virtue of the impossibility of forming a closed-flux circuit, it is not currently possible to reconcile an increase in the ferromagnetic resonance frequency of the magnetic element with the optimization of the electromagnetic confinement around the inductive element. Consequently, this results in components with diminished performance (low gain over L˜10% and reduced Q<10 at 1 GHz) that are unusable for the desired application (RF circuits).

### SUMMARY OF THE INVENTION

One object of the invention is to produce a continuous magnetic element with a high ferromagnetic resonance frequency that still remains compatible with the usual dimensions of planar or solenoidal inductors and of coplanar lines or microstrips.

Another object is to make the fabrication of closed, or virtually closed, magnetic circuits allowing an improved closure of magnetic flux possible.

According to one embodiment, the reinforcement of the intrinsic magnetic anisotropy of the material is obtained by using another contribution of intrinsic origin associated with the growth of the magnetic film from a material flux whose principal direction makes a non-zero angle of incidence with respect to the plane of the substrate onto which the film is deposited.

Furthermore, the invention aims to maximize this effect so as to increase the ferromagnetic frequency into the desired range. Since the latter is naturally accompanied by a reduction in the permeability, the idea will be to preferably use materials with high magnetization (>1 T) in order to preserve high permeability values. In other words, one advantage includes adding a contribution to the intrinsic anisotropy of the material by the formation of a microstructure having a preferential direction of growth whose axis is not orthogonal (normal) to the plane of the substrate.

In the most representative case of polycrystalline or nanocrystalline films, the natural tendency of these films to develop a granular structure of the columnar type, in other words whose grains naturally exhibit a aspect ratio greater than unity in the direction of the flux of incident material, will be advantageously exploited.

In the case of amorphous films, there also exists a sensitivity to the direction of the incident flux despite the absence of a crystalline character. This is then referred to as columnar texture, in other words, including clusters preferentially aligned in the direction of the incident flux.

Thus, according to one embodiment, a radiofrequency device is provided that comprises an electrically conducting element associated with at least a first continuous magnetic element comprising a substrate coated with a magnetic film having a granular structure, with grains inclined to the normal to the substrate, or a columnar texture inclined to the normal to the substrate.

Thus, the continuous magnetic element allows the electromagnetic flux leakages to be reduced and the inclination of the grains or of the columnar texture of the magnetic film allows the intrinsic anisotropy of the material, and hence its ferromagnetic resonance frequency, to be increased.

In an advantageous manner, the direction of the inclination axis of the grains or columnar strands projected into the plane of the substrate coincides with that of the magnetic field applied during the deposition. In particular, in the case of planar inductors and coplanar lines or microstrips, in order to further contribute to obtaining a closed, or almost closed, magnetic circuit, the distance between the magnetic elements (upper and lower) and the conductor is advantageously short, typically less than or equal to 5 μm. The magnetic film is, for example, an alloy comprising at least one element taken from the group comprising iron (Fe), cobalt (Co), nickel (Ni). The magnetic film may, for example, be an FeCoXN or FeCoXO or FeCoXNO or FeXN or FeXO or FeXNO alloy, X being chosen from among the following elements: Zr, Nb, Mo, Ru, Rh, Pd, Hf, Ta, W, Ir, Pt, Al, Si, Ti, V, Cr, Mn, Cu and the lanthanides (rare earths). An especially noteworthy alloy is the alloy FeXNO.

Nevertheless, the high-magnetization alloys of the granular type FeHfN(O), which naturally exhibit a microstructure of columnar grains dispersed within an amorphous structure, are particularly well suited to the devices. Indeed, the increase in the intrinsic anisotropy of the material is significant for FeHfN, and it is even more so for an alloy of FeHfNO. The reason is that the aspect ratio of the (non-equiaxed) grains makes them all the more predisposed to the effect being sought, as the intergranular exchange coupling is partially released, owing to the dispersion of the ferromagnetic grains within a matrix rendered weakly magnetic (low magnetization) by selective oxidation with the FeHfNO material.

The inclination angle of the grains or of the columnar texture to the normal to the substrate is greater than 0° and less than 90°, and is advantageously in the range between 20° and 80°. The first magnetic element may be disposed on top of or underneath the conducting element.

Nevertheless, it is especially advantageous, in order to further improve the performance of the device, for the latter to additionally comprise a second continuous magnetic element comprising a substrate coated with a magnetic film having a granular structure with grains inclined to the normal to the substrate or a columnar texture inclined to the normal to the substrate. The second magnetic element is preferably identical to the first magnetic element. However, the anisotropy directions in the plane of the two magnetic elements may differ and have, for example, an angle of 90° for a solenoid using a frame closed in the plane.

The conducting element can be a spiral element, a coplanar line element or microstrip, the conducting element then being sandwiched between the two continuous magnetic elements. The conducting element can be a toroidal element so as to form solenoidal inductors, the conducting element then being formed around a continuous magnetic element. By using at least four continuous magnetic elements, a toroidal solenoid inductor can be formed. As a variant, the conducting element can be an element of a coplanar line or microstrip sandwiched between two continuous magnetic elements, so as to perform filtering functions (low-pass or noise attenuator, bandpass, etc . . .).

According to another embodiment, a process is provided for the fabrication of a magnetic element of a radiofrequency device such as defined hereinabove, this process comprising physical vapor deposition onto an inclined substrate, for example, oblique ion-beam sputtering onto the substrate in the presence of a magnetic field.

According to another embodiment, a target contains the substance to be deposited, and a receiving substrate is subjected to a magnetic field. An auxiliary abrasive source may optionally be used. The angle of incidence between the main direction of the flux of material to be deposited from the target and the normal to the substrate that receives the deposition can be set at a value different from zero by adjusting the inclination angles of the abrasive source and/or of the target and/or of the substrate.

In the case of an evaporation or cathodic sputtering process, the deposition is advantageously effected onto a substrate that is not parallel to the target (the flux of material being normal to the target), in other words, onto a substrate whose normal makes a non-zero angle with the normal to the target.

In the case of a process using an external abrasive source, such as an ion gun for the ion-beam sputtering, or a laser for laser ablation, the directionality of the emission of material also allows the angle between the direction of material flux and the normal to the target to be adjusted. The direction of the magnetic field is preferably orthogonal to the direction of the axes about which the abrasive source, the target, and the substrate are pivotable. This allows anisotropy directions of the material that are, on the one hand, induced by the field during the deposition process and, on the other hand, due to the inclination of the grains, are collinear, which allows a direct cumulative effect and simple (linear) control of the anisotropy reinforcement effect.

The ion-beam sputtering deposition technique is well suited from an industrial point of view since it allows the type of magnetic material used to be synthesized over large area substrates compatible with the usual dimensions used in microelectronics (in other words, wafers having diameters up to 300 mm). Oblique ion-beam sputtering is, for example, effected by an FeX target, in the presence of nitrogen and/or oxygen.

### BRIEF DESCRIPTION OF THE DRAWINGS

Other advantages and features of the invention will become apparent upon examining the detailed description of non-limiting embodiments and their implementation and the appended drawings in which:

FIG. 1 schematically illustrates an embodiment of a radiofrequency device according to the invention.

FIG. 2 is a partial top view of the device in FIG. 1.

FIG. 3 is a schematic partial cross section along the line III-III in FIG. 2.

FIGS. 4 and 5 schematically illustrate an embodiment of a process according to the invention.

FIGS. 6 to 8 schematically illustrate other embodiments of a radiofrequency device according to the invention.

### DETAILED DESCRIPTION OF THE PREFERRED EMBODIMENTS

In FIG. 1, the reference DRF denotes a radiofrequency device according to an embodiment of the invention comprising a conducting element IS formed from a spiral coil sandwiched between a first magnetic element EM situated on top of the coil IS and a second magnetic element EM2 is situated underneath the coil. The two magnetic elements are continuous elements and are advantageously separated from the conducting element IS by a relatively small distance d. This distance d is, for example, less than or equal to 5 μm. The configuration of the device DRF allows a virtually-closed magnetic circuit to be obtained using continuous magnetic elements.

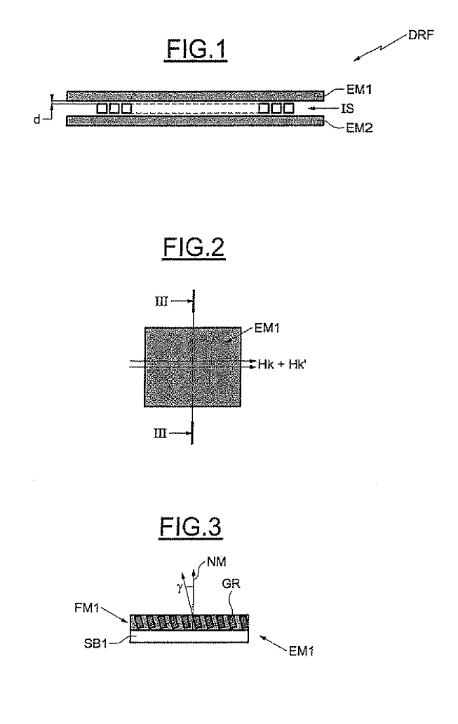

As is illustrated more particularly in FIGS. 2 and 3, each magnetic element EM1 comprises a substrate SB1 coated with a continuous granular magnetic film SM1 whose grains exhibit an oblique orientation to the normal NM to the substrate SB1. The orientation angle γ is, for example, around 60° and may, more generally, be in the range from 20° to 80°.

As illustrated more particularly in FIG. 2, original direction of easy magnetization Hk, intrinsic to the magnetic material and induced during the deposition of the latter (as will be explained in more detail hereinbelow for a particular embodiment), is collinear with the direction of original easy magnetization Hk′ due to the inclination of the grains GR of the magnetic film. Thus, the intrinsic anisotropy Hk of the magnetic material is reinforced by the intrinsic contribution Hk′ due to the inclination of the grains or the columnar texture of the film.

By way of example, with a magnetization Ms of 1.9 T, a contribution Hk′ of around 200 Oe could be chosen for a ferromagnetic resonance frequency equal to 6 GHz, which is of the same order of magnitude as that resulting from the demagnetizing effect used in the prior art open magnetic circuit radiofrequency devices. It is particularly advantageous to use magnetic materials with a strongly columnar growth and exhibiting the dispersion of the crystalline phase (columnar grains) within a disordered, for example, amorphous matrix.

The aspect ratio of the (non-equiaxed) grains leads to an intrinsic anisotropy direction in the direction of the greatest elongation. The clustering of the grains in the case of a conventional microstructure that is dense and homogeneous (as regards the grains and grain boundaries) cancels out this local contribution by providing a very high intergranular exchange coupling. The local effects due to the grains are collectively felt at the film level with an amplitude proportional to the residual intergranular exchange coupling in the case of a dispersion of the grains within a second phase, exhibiting different characteristics from those of the grains (notably a much weaker magnetization if this is an amorphous phase). This residual intergranular exchange coupling mainly depends on the diameter of the grains and on the distance between the grains. The effect will be more marked the more the direction of the greatest elongation of the grains (direction of growth) exhibits a non-zero inclination angle γ, in accordance with the invention.

The materials advantageously exhibiting these two characteristics are FeXN, FeXO and FeXNO alloys, and especially FeHfN or FeHfNO alloys. Indeed, these materials exhibit the particular property of having a very strong columnar natural growth (aspect ratio>10) associated with a microstructure advantageously combining small grain size (of diameter from 100 to 5 nm) dispersed in a regular and controlled manner, and (intergranular distance) within a more or less amorphous phase of Fe rich in XN, XO or XNO. The latter exhibits a magnetization that is significantly weaker than that of the purely crystalline phase (typically from 50% up to 100%). The latter case corresponds to a non-magnetic intergranular phase (zero magnetization).

The formation of the magnetic film of the magnetic element is advantageously effected by using an ion-beam sputtering (IBS) deposition process, which offers a wide flexibility in terms of exploitation of the angle between the flux of material to be deposited and the substrate, and which is not allowed by the conventional plasma sputtering techniques. Furthermore, the IBS deposition technique is well suited to the synthesis of this kind of material, and it allows application of the physical effect of inclined grain growth over a large surface area compatible with that used in microelectronics, for example, wafers with diameters of up to 300 mm.

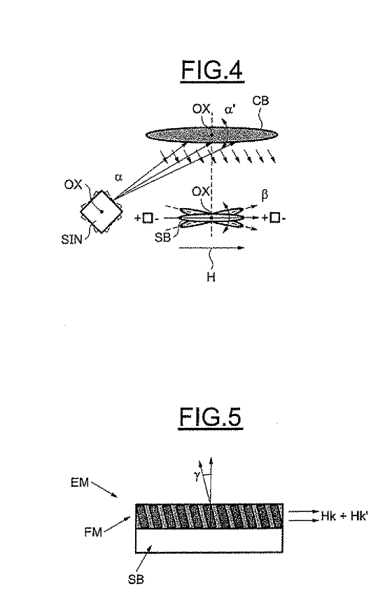

An exemplary embodiment of such a deposition technique is illustrated in FIG. 4. More precisely, a source of ions SIN capable of pivoting about an axis Ox generates a main flux of ions, for example, of argon, in the direction of a target CB comprising, for example, FeX. The target CB is consequently bombarded by the main argon flux in the presence of nitrogen and oxygen (when FeXNO alloys are desired to be obtained), at room temperature.

The FeX particles extracted from the target are then sputtered onto the substrate SB with a certain angle of incidence. This angle of incidence may be adjusted as a function of the inclination angle α of the source SIN about the axis Ox, of an inclination angle β of the substrate to the normal to the target, and of the inclination angle α′ of the target CB about the axis Ox.

The growth of the magnetic film is carried out in the presence of a magnetic field H applied in the plane of the substrate and advantageously orthogonal to the pivot axis Ox of the source SIN and to the axis Ox of the substrate holder. The intensity of this uniaxial magnetic field is for example from around 100 to 200 Oe.

The nitridation and oxidation processes are respectively controlled by injected concentration ratios of secondary (reactive) gas. The relative concentration ratio of nitrogen is defined by the ratio: N₂/(Ar+N₂+O₂) and the oxygen concentration ratio by O₂/(Ar+N₂+O₂). These concentrations can typically vary over the range 0% to 25%. The thicknesses of the films formed are typically in the range between 500 Å and 5000 Å. The atomic percentage of nitrogen is preferably in the range between 5% and 20%. Indeed, for such a percentage, the thin films include a fine nanostructure comprising nanoscale grains of bcc or bct FeXN randomly distributed within an amorphous X-rich matrix.

The nitrogen is incorporated in an interstitial position within the crystal lattice of the FeX nanograins up to the solid solution saturation in the grains (around 15-20 at %). This incorporation is accompanied by a significant expansion of the FeX crystal lattice (up to 5%), whose consequence is a reduction in the mean grain size.

The oxygen is preferably incorporated into the X-rich amorphous phase surrounding the FeXN grains. The advantage of this process is the very low oxidation of the FeXN ferromagnetic phase, which allows a high magnetization to be conserved.

Under these conditions, the FeXN grains have a mean diameter of the order of 10 to 2 nm with a mean intergranular distance of the order of 5 to 1 nm. This allows soft magnetic properties to be obtained (Hc≦5 Oe). These films exhibit an induced magnetic anisotropy characterized by an anisotropy field of the order of 10 to 40 Oe. These films retain a high saturation magnetization, typically of the order of 1.9 to 1.0 T. The electrical resistivity of the films increases with increasing concentration of nitrogen and of oxygen up to a value typically in the range between 500 and 1000 μΩ·cm. After growth of the magnetic film, a structure, such as that illustrated in FIG. 5, is obtained with grains exhibiting an inclination γ to the normal to the substrate and collinear anisotropy directions Hk and Hk′.

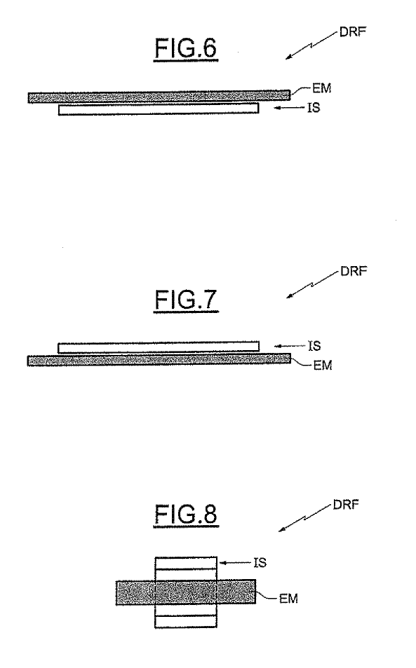

The invention is not limited to the embodiments and implementations described hereinabove. More precisely, a device DRF may only comprise a single magnetic element EM which can be disposed on top of (FIG. 6) or else underneath (FIG. 7) the conducting element IS. This conducting element IS can, for example, be a spiral, a coplanar line or a microstrip line.

Furthermore, the conducting element IS can, as illustrated in FIG. 8, include a solenoidal winding formed around a continuous magnetic element EM. This notably allows the production of radiofrequency inductive devices that employ a magnetic circuit that is continuous and virtually closed around an inductive element. The advantage includes an optimal confinement of the magnetic field within the circuit.

In the case of spiral inductors, this allows gains in open inductance values greater than 100% and higher quality factors Q, for example, greater than or equal to 30 for a frequency typically in the range between 1 and 2 GHz. In the case of coplanar lines or microstrips, gains in open inductance of over 400% may be obtained, together with quality factors that are even higher, for example, greater than or equal to 50 for a frequency typically in the range between 1 and 5 GHz. In the case of coplanar lines or microstrips, filtering functions of the notch, low-pass, and bandpass types are also possible with attenuations typically greater than −10 dB per mm of line and per μm of deposited material thickness.

1-19. (canceled)

20. A radio frequency device comprising:
an electrically conducting element; and
a first continuous magnetic element associated with said electrically conducting element and comprising
a substrate, and
a magnetic film coating said substrate and comprising grains inclined to a normal of said substrate.

21. The radio frequency device according to claim 20, wherein said magnetic film comprises at least one of Fe, Co, and Ni.

22. The radio frequency device according to claim 20 wherein said magnetic film comprises at least one of an FeCoXN, FeCoXO, FeCoXNO, FeXN, FeXO, and FeXNO alloy; and wherein X comprises one of Zr, Nb, Mo, Ru, Rh, Pd, Hf, Ta, W, Ir, Pt, Al, Si, Ti, V, Cr, Mn, Cu, and the Lanthanides.

23. The radio frequency device according to claim 21, wherein said magnetic film comprises an FeHfNO alloy.

24. The radio frequency device according to claim 20, wherein said grains have an angle of inclination associated therewith; and wherein said angle of inclination is in a range between about 20° and 80°.

25. The radio frequency device according to claim 20, wherein said first continuous magnetic element is positioned on top of or underneath said electrically conducting element.

26. The radio frequency device according to claim 20 further comprising:
a second continuous magnetic element associated with said electrically conducting element and comprising
a substrate, and
a magnetic film coating said substrate and comprising grains inclined to a normal of said substrate;
said electrically conducting element being positioned between said first and second continuous magnetic elements.

27. The radio frequency device according to claim 26, wherein said second continuous magnetic element is identical to said first continuous magnetic element.

28. The radio frequency device according to claim 20, wherein said electrically conducting element comprises a spiral element.

29. The radio frequency device according to claim 20, wherein said electrically conducting element comprises one of a coplanar line and microstrip.

30. The radio frequency device according to claim 20, wherein said electrically conducting element comprises a solenoid winding surrounding the first continuous magnetic element.

31. A radio frequency device comprising:
an electrically conducting element;
a pair of magnetic elements adjacent opposite sides of said electrically conducting element, each comprising
a substrate, and
a magnetic film coating said substrate and comprising grains inclined to a normal of said substrate.

32. The radio frequency device according to claim 31, wherein said magnetic film comprises at least one of Fe, Co, and Ni.

33. The radio frequency device according to claim 31 wherein said magnetic film comprises at least one of an FeCoXN, FeCoXO, FeCoXNO, FeXN, FeXO, and FeXNO alloy; and wherein X comprises one of Zr, Nb, Mo, Ru, Rh, Pd, Hf, Ta, W, Ir, Pt, Al, Si, Ti, V, Cr, Mn, Cu, and the Lanthanides.

34. The radio frequency device according to claim 31, wherein said grains have an angle of inclination associated therewith; and wherein said angle of inclination is in a range between about 20° and 80°.

35. A method of making a radio frequency device comprising:
performing a physical vapor deposition of a magnetic film onto an inclined substrate to form a continuous magnetic element so that the magnetic film comprises grains inclined to a normal of the substrate; and
associating an electrically conducting element with the continuous magnetic element to thereby form the radio frequency device.

36. The method according to claim 35, wherein performing the physical vapor deposition is performed by at least one of cathode sputtering and evaporation.

37. The method according to claim 35, wherein performing the physical vapor deposition is performed by oblique ion-beam sputtering onto the inclined substrate.

38. The method according to claim 37, wherein the oblique ion-beam sputtering is performed by an ion source and a sputtering target; and wherein the ion source and sputtering target are pivotable about an axis.

39. The method according to claim 35 wherein performing the physical vapor deposition is performed by a laser and sputtering target; and wherein the laser and sputtering target are pivotable about an axis.

40. The method according to claim 35, wherein the inclined substrate is subjected to a magnetic field applied in a plane of the inclined substrate and whose direction is orthogonal to a pivot axis.

41. The method according to claim 40, wherein the inclined substrate is pivotable about the pivot axis; and wherein a magnetic field is applied in the plane of the inclined substrate with a direction orthogonal to the pivot axis.

42. The method according to claim 35, wherein performing the physical vapor deposition is performed by at least one of a CoFeX and FeX alloy target in the presence of at least one of nitrogen and oxygen.
